(19) United States
(12) Patent Application Publication
(10) Pub. No.: US 2001/0003673 A1
(43) Pub. Date: Jun. 14, 2001

(54) ETCH BIAS TUNING FOR ENHANCEMENT OF STEPPER LIFE

(76) Inventors: WARREN T. YU, SAN JOSE, CA (US); SCOTT BELL, SAN JOSE, CA (US)

Correspondence Address: MCDERMOTT WILL & EMERY, 600 13TH STREET, N.W., WASHINGTON, DC, 20005-3096, US

(21) Appl. No.: 09/245,083

(22) Filed: Feb. 5, 1999

(51) Int. Cl. H01L 21/302

(52) U.S. Cl. 438/706; 438/710

(57) ABSTRACT

The life of a stepper is prolonged, while achieving a design L/S by changing the L/S values of a reticle with respect to the design L/S to facilitate printing. Etch bias is then conducted to vary etching so that the resulting L/S corresponds to the design L/S. In this way, the load on the stepper mechanism which moves the wafters about with respect to the optics in which the reticle is mounted is reduced.

### FIELD OF THE INVENTION

The present invention relates generally to the manufacture of semiconductor devices such as those used in flash memories and the like, and more specifically to a manufacturing technique that employs etch plasma polymer formation in a manner which enables the operational life of a stepper to be prolonged.

### BACKGROUND ART

As very large scale integration (VLSI) chip dimensions continuously shrink, a problem is encountered that the surface of a workpiece, such as a semiconductor wafer and the layers formed thereon, are not flat and the disturbing effect of this lack of flatness increases as the dimensions reduce. Thus, even assuming that a reticle, which is held in a wafer stepper, is perfectly flat, because of the lack of flatness of the surface of the workpiece surface thereunder, there will be a variation in spacings between the reticle and the surfaces of the photolithographic material or other materials.

These variations become increasingly relevant as the dimensions shrink. For example, during exposure of the newly deposited photolithographic masking material formed on the workpiece, it is necessary, in order to achieve a reasonably correct focus of the radiant energy which passes through the reticle to the workpiece, that the variations in levels of the workpiece surface relative to the reticle be minimized in the areas being exposed at a given time. Accordingly, it is necessary to provide a technique which affords the manufacturer the ability to determine the degree to which the reticle has been leveled relative to the surface of the workpiece so that adjustments can be made to correct the performance of the stepper.

In more detail, the above-mentioned stepper devices are step-and-repeat lithographic system cameras in which a workpiece is exposed over and over by two dimensional translations of the workpiece beneath the reticle. These steppers use a reticle as the object whose image is projected either directly in a 1:1 projection system or through a stepper lens onto the surface of a workpiece with the reduced image size. In the case of a reduced image system, the pattern transfer from the reticle to the mask on the wafer is accomplished by optically reducing the image to the correct dimensions while simultaneously focusing it onto a specified region of the wafer. After each exposure, the process continues with the wafer being translated to the next desired imaging position where the image is exposed again in the same way. The image is thus sequentially exposed, until the desired regions of the workpiece have been exposed. In each position of the workpiece, the process of leveling must be repeated to achieve the best possible focus of the reticle image upon the region of the workpiece being exposed.

Use has been made in the past of a line/space pattern to check and adjust stepper leveling performance. However a great deal of time is required to measure Critical Dimension (CD) value by means of Scanning Electron Microscopy (SEM) and to then adjust the operation of the stepper. In addition to the time required to achieve the feed-back control, the load on the stepper is such as to reduce its useful lifetime. As steppers are extremely expensive pieces of machinery, techniques which enable the operative life of the device to be extended are extremely desirable. That is to say, production costs are affected by both the cost of the machine and the amount of downtime which is involved in replacing the device. The fact that steppers must be located in and set up in clean rooms/clean environments further tends to prolong the downtime and, accordingly, complicates matters as installation must be carefully carried out with minimum generation of microsized pieces of dust and the like.

### SUMMARY OF THE INVENTION

It is therefore a feature of the present invention to provide a technique via which stepper printing is made easier and which, thus, reduces the load on the device, thereby prolonging its operative life.

It is a further feature of the present invention to provide a method which enables the reticle, which is used in connection with the printing process, to be formed in a manner wherein a line/space (L/S) ratio is varied in a manner which enlarges the width of the space and reduces the width of the lines and which utilizes a negative bias etch to bring the width of the spaces in a manner wherein the L/S is different from the reticle L/S and meets the design L/S.

These and other features of the invention are achieved by an arrangement which changes the L/S of a reticle with respect to design L/S to facilitate printing. Etch bias is then conducted to vary the results of the etching so that the resulting L/S is the same as the design L/S. This technique enables a reduction in the load on the mechanism of a stepper which moves the wafters about with respect to the optics in which the reticle is mounted, thereby, prolonging the life of the stepper.

More specifically, a first aspect of the present invention resides in a method of semiconductor production with prolongs the life of a stepper used in connection therewith, comprising the steps of: designing a reticle to have a line to space ratio L/S which is different from a design L/S and which is such that a width of the line is changed by a predetermined amount and a width of the space is oppositely changed by the same predetermined amount; and using etch bias to reduce the change in the width of the space as determined by the reticle, by the predetermined amount and thus modify the width of the line by the predetermined amount to achieve the L/S to the design L/S.

In accordance with this method, the step of using etch bias comprises tuning the polymer formation in an etch plasma in a manner which reduces the width of the space back to the design size.

A second aspect of the invention resides in a method of semiconductor production which prolongs the life of a stepper used in connection therewith, comprising the steps of: modifying a L/S ratio of a reticle with respect to a design L/S such that the smaller of the two widths is increased by a predetermined amount and the larger of the two widths is decreased by the predetermined amount to facilitate stepper printing; using the reticle to imprint a L/S pattern on a layer of photo resist formed on a substrate; removing a portion of the photo resist in accordance with the image imprinting to form an etch mask; and using a negative bias etching to etch the substrate and to reduce the width of the smaller two widths by the predetermined amount and thus cause the width of the larger of the two widths to be increased by the predetermined amount, thereby rectifying the resulting L/S to the design L/S.

In this method the step of using etch bias comprises the step of tuning polymer formation in an etch plasma to reduce the width of the space back to the design size.

Another aspect of the invention resides in an apparatus for prolonging stepper life, comprising: a reticle having a line to space ratio US which is different from a design L/S wherein a width of the line is different by a predetermined amount and a width of the space is oppositely different by the same predetermined amount; means for imprinting an image produced by the reticle on a layer of photo resist which is formed over a surface of a substrate and for creating an etching mask; and etching means for biasing an etch through the etching mask and for reducing the width of the space as determined by the reticle by the predetermined amount thereby modifying the width of the line by the predetermined amount to return to the design L/S.

In this apparatus, the etching means includes means for tuning polymer formation in an etch plasma which reduces the space which is formed by the etching back to the width the design L/S.

### BRIEF SUMMARY OF THE DRAWINGS

The various features and advantages of the present invention will become more clearly appreciated as a description of the embodiments is given with reference to the appended drawings in which:

FIG. 1 is a schematic perspective view showing a stepper which has a table on which a wafer is supported and an optical system in which a reticle is disposed; and

FIGS. 2A-2D schematically demonstrate the differences in spacing and line width which occur in accordance with the present invention.

### DETAILED DESCRIPTION OF THE PREFERRED EMBODIMENTS

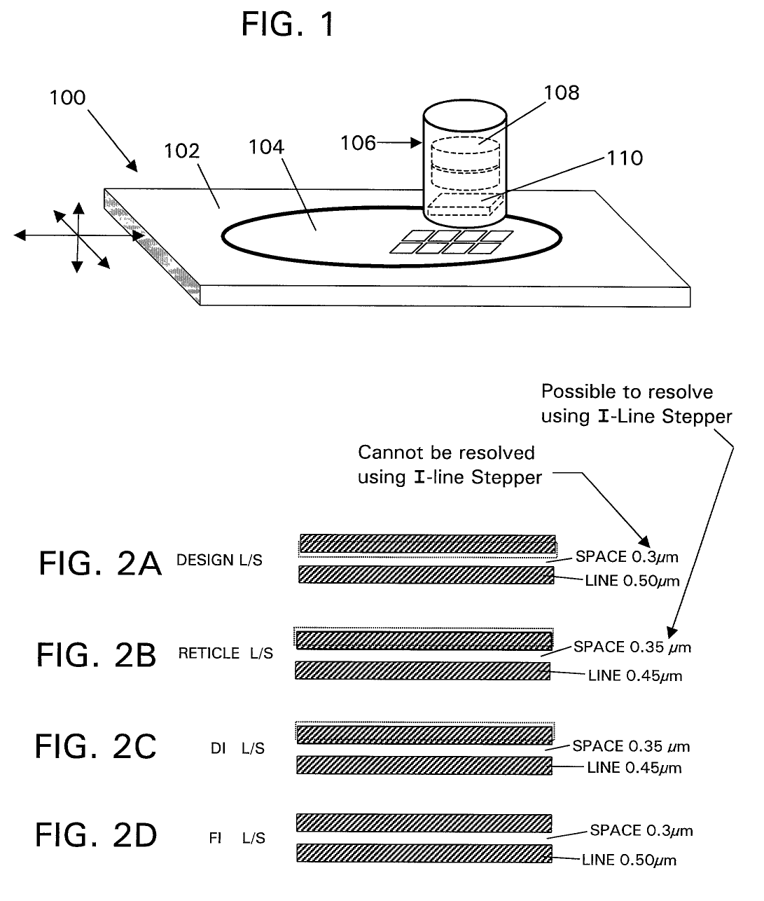

FIG. 1 schematically shows a stepper 100 which includes a table 102 adapted to support and hold wafers 104 thereon, and an optical system 106 which includes a source of radiant energy 108 and a reticle 110 for determining the pattern which is imprinted on the wafer. As will be appreciated, this view is highly schematic and omits all but the basic elements of the stepper. Further, only a limited number of chip outlines are shown and are not drawn to scale. For further details pertaining to the construction, control and operation of steppers reference may be had to U.S. Pat. No. 5,392,361 issued on Feb. 21, 1995 in the name of Imaizumi et al.

In accordance with the present invention, the reticle 110 is arranged such that the L/S is changed from the design L/S in a manner which increases the smaller of the two values by a predetermined increment and reduces the larger of the two by the same increment. For example, given that the design line width is 0.50 μm and the space is 0.30 μm (viz., a LS of 0.50/0.30) in the manner illustrated in FIG. 2A. In accordance with an embodiment of the present invention, the line width is reduced by 0.05 μm while the space is increased by the same value (see FIG. 2B). A space of 0.30 μm cannot be resolved using a I-line stepper. On the other hand, it is possible to resolve a line of 0.35 μm with such a device.

By increasing the width of the smaller of the two values, stepper printing is rendered easier and the load on the stepper is reduced. This inherently prolongs the life of the stepper arrangement.

In order achieve the desired design L/S, the present invention compensates for the increased width of the space by using a negative bias during the etching process which follows the formation of an etching mask using the image produced using the above described reticle. More specifically, by tuning the polymer formation in the etch plasma it is possible to reproducibly reduce the width of the space from 0.35 μm to 0.30 μm for example. This of course, automatically increases the width of the line by the amount the space is narrowed and thus causes the final product to exhibit the design L/S.

An example of such a polymer tuning is as follows:

When etching a gate stack consisting of a inorganic BARC, such as SiOn, on top of polysilicon, the chemistry of the SiON etch step can be moulated to result in a CO growth with respect to the intial lithography. CO growth can be achieved by etching the SiON with a CHF₃/CF₄/O₂/Ar process. Conditions for CO growth occur at higher CHF₃, lower O₂ and lower pressure. A typical process is as follows:

Pressure=50-80 mT

Power=280-560 Watt

CHF₃=10-20 sccm

O₂=3-7 sccm

CF₄=20-40 sccm

Ar=70-130 sccm

The present invention enjoys industrial applicability in the manufacture of various types of semiconductor devices. The present invention is particularly applicable to the manufacture of semiconductor devices having a dimension of about 0.18 micron and under.

It is submitted that given the preceding disclosure, the methodology involves the use of conventional methodology and equipment not elaborated herein. Further, although the present invention has been disclosed with reference to only limited embodiments and examples, the various modifications and changes which can be made without departing from the invention, which is limited only by the appended claims, will be readily apparent to those skill in this art.

What is claimed is:

1. A method of semiconductor production with prolongs the life of a stepper used in connection therewith, the method comprising the steps of:
designing a reticle to have a line to space ratio L/S which is different from a design L/S and which is such that a width of the line is changed by a predetermined amount and a width of the space is oppositely changed by the same predetermined amount; and
using etch bias to reduce the change in the width of the space as determined by the reticle, by said predetermined amount and thus modify the width of the line by the predetermined amount to achieve the design L/S.

2. The method as set forth in claim 1, wherein the step of using etch bias comprises the step of tuning polymer formation in an etch plasma to reduce the width of the space to the design size.

3. A method of semiconductor production which prolongs the life of a stepper used in connection therewith, the method comprising the steps of:
modifying a line to space ratio (L/S) of a reticle with respect to a design L/S such that the smaller of the two widths is increased by a predetermined amount and the larger of the two widths is decreased by the predetermined amount to facilitate stepper printing;
using the reticle to imprint a L/S pattern on a layer of photoresist formed on a substrate;
removing a portion of the photo resist in accordance with the image imprinting to form an etch mask; and
using a negative bias etching to etch the substrate and to reduce the width of the smaller two widths by the predetermined amount and thus cause the width of the larger of the two widths to be increased by the predetermined amount, thereby rectifying the resulting L/S to the design L/S.

4. The method as set forth in claim 3, wherein the step of using etch bias comprises the step of tuning polymer formation in an etch plasma, to reduce the width of the space to the design size.

5. An apparatus for prolonging stepper life, the apparatus comprising:
a reticle having a line to space ratio L/S which is different from a design L/S wherein a width of the line is different by a predetermined amount and a width of the space is oppositely different by the same predetermined amount;
means for imprinting an image produced by the reticle on a layer of photoresist which is formed over a surface of a substrate and for creating an etching mask; and
etching means for biasing an etch through the etching mask and for reducing the width of the space as determined by the reticle by said predetermined amount, thereby modifying the width of the line by the predetermined amount to return to the design L/S.

6. The apparatus as set forth in claim 5, wherein said etching means includes means for tuning polymer formation in an etch plasma which reduces the space which is formed by the etching back to the width the design L/S.
